(19) United States
(12) Patent Application Publication
(10) Pub. No.: US 2008/0194074 A1
(43) Pub. Date: Aug. 14, 2008

(54) ANNEALING PROCESS OF POLYSILIZANE LAYER AND METHOD OF FORMING ISOLATION LAYER OF SEMICONDUCTOR DEVICE EMPLOYING THE SAME

(75) Inventors: Kwang Seok Jeon, Seongnam-si (KR); Kwang Chul Joo, Yongin-si (KR); Wan Sup Shin, Seoul (KR); Kwang Hyun Yun, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/026,431

(22) Filed: Feb. 5, 2008

(30) Foreign Application Priority Data
Feb. 9, 2007 (KR) 2007-13676

(51) Int. Cl. H01L 21/76; H01L 21/311; H01L 21/469

(52) U.S. Cl. 438/424; 438/697; 438/778; 257/E21.243; 257/E21.546; 257/E21.487

(57) ABSTRACT

A method of forming an isolation layer of a semiconductor device is provided. A wafer having a polysilizane (PSZ) layer formed is loaded into a chamber while a loading temperature is maintained in the chamber. An oxygen gas is supplied to the chamber. After the loading, a temperature within the chamber is raised up to a process temperature. Subsequently, the PSZ layer is cured in the chamber maintaining the process temperature. During the curing step, vapor is supplied to the chamber such that a ratio of the oxygen gas and the vapor is set in the range of 1:1 to 50:1. The inside of the chamber is purged by supplying an inert gas to the chamber where the oxygen gas and the vapor are blocked to be supplied.

### CROSS-REFERENCES TO RELATED APPLICATIONS

The present application claims priority to Korean patent application number 10-2007-013676, filed on Feb. 9, 2007, which is incorporated by reference in its entirety.

### BACKGROUND

The present invention relates to a method of forming an isolation layer of a semiconductor device and, more particularly, to a method of forming an isolation layer of a semiconductor device, in which it can remove the impurities of a polysilizane (PSZ) layer.

In semiconductor devices requiring the design rule of 70 nm or less, a Shallow Trench Isolation (STI) process that is able to significantly reduce stress applied to a wafer substrate is generally used. The STI process is the technology for forming trenches having a specific depth in a semiconductor substrate, depositing an oxide layer on the trenches using a Chemical Vapor Deposition (hereinafter, referred to as “CVD”), and etching the oxide layer using a Chemical Mechanical Polishing (hereinafter, referred to as “CMP”), thus forming an isolation layer.

FIG. 1 is a sectional view illustrating a conventional method of forming an isolation layer of a semiconductor device.

A screen oxide layer 101 and a nitride layer 102 are sequentially formed over a semiconductor substrate 100. The nitride layer 102, the screen oxide layer 101 and the semiconductor substrate 100 are sequentially etched, thus forming trenches 104. The trenches 104 are gap filled with an O₃-TEOS layer 103 and a steam anneal process is then carried out. Though not shown in FIG. 1, the O₃-TEOS layer 103, the nitride layer 102 and the screen oxide layer 101 are polished using a CMP process so that the O₃-TEOS layer 103 remains within the trenches 104, thereby forming a STI type isolation layer.

However, the above-described process can generate voids 105 and seams 106 in the isolation layer. The voids 105 and the seams 106 cause to degrade the electrical properties and reliability of the semiconductor device.

### SUMMARY

The present invention is directed to a method of forming an isolation layer without voids or seams while easily removing impurities, which are included in a PSZ material in large quantities, by using the PSZ material as a material for forming the isolation layer and performing an annealing process in a state where vapor and an oxygen gas are mixed.

According to an aspect of the present invention, an annealing method of an PSZ layer includes loading a wafer on which a PSZ layer is formed into a chamber in which a loading temperature is maintained and to which an oxygen gas is supplied, and raising a temperature within the chamber from the loading temperature to a process temperature. The annealing method further includes curing the PSZ layer in a state where the process temperature is maintained, vapor is supplied to the chamber, and a ratio of the oxygen gas and the vapor is set in the range of 1:1 to 50:1, purging the inside of the chamber by blocking both the oxygen gas and the vapor supplied to the chamber and supplying an inert gas to the chamber. The temperature within the chamber is lowered from the process temperature to an unloading temperature. The wafer is unloaded outside the chamber while the unloading temperature is maintained.

According to another aspect of the present invention, a method of forming an isolation layer of a semiconductor device includes forming a PSZ layer over a substrate in which trenches are formed, loading a wafer on which the PSZ layer is formed into a chamber in which a loading temperature is maintained and to which an oxygen gas is supplied, and raising a temperature within the chamber from the loading temperature to a process temperature. The method further includes curing the PSZ layer in a state where the process temperature is maintained, vapor is supplied to the chamber, and a ratio of the oxygen gas and the vapor is set in the range of 1:1 to 50:1, and purging the inside of the chamber by supplying an inert gas to the chamber wherein the oxygen gas and the vapor are supplied to the chamber. The temperature is lowered within the chamber from the process temperature to an unloading temperature. The method still further includes unloading the wafer outside the chamber in a state where the unloading temperature is maintained, and forming the isolation layer within the trenches by polishing the PSZ layer using a Chemical Mechanical Polishing (CMP) process.

### BRIEF DESCRIPTION OF THE DRAWINGS

FIG. 1 is a sectional view illustrating a conventional method of forming an isolation layer of a semiconductor device;

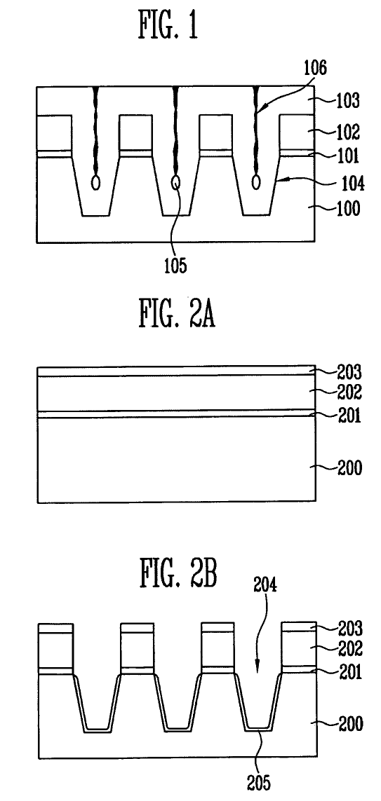

FIGS. 2A to 2D are sectional views illustrating a method of forming an isolation layer of a semiconductor device according to an embodiment of the present invention;

FIG. 3 shows the structure of a chamber and gas line for illustrating the annealing process of a PSZ layer according to an embodiment of the present invention;

FIG. 4 shows a process recipe for illustrating the annealing process of the PSZ layer according to an embodiment of the present invention; and

FIG. 5 illustrates combined energy analysis results obtained by employing the Fourier Transform Infrared (FTIR) spectrometer according to an embodiment of the present invention.

### DESCRIPTION OF SPECIFIC EMBODIMENTS

Now, specific embodiments according to the present invention will be described with reference to the accompanying drawings.

However, the present invention is not limited to the disclosed embodiments, but may be implemented in various manners. The embodiments are provided to complete the disclosure of the present invention and to allow those having ordinary skill in the art to understand the scope of the present invention. The present invention is defined by the category of the claims.

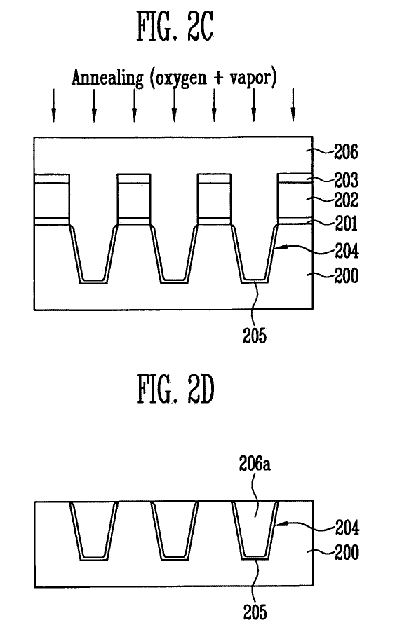

FIGS. 2A to 2D are sectional views illustrating a method of forming an isolation layer of a semiconductor device according to an embodiment of the present invention.

Referring to FIG. 2A, a screen oxide layer 201, a pad nitride layer 202 and a hard mask layer 203 are sequentially laminated over a semiconductor substrate 200.

The screen oxide layer 201 may be formed to a thickness of 50 to 80 angstrom. The screen oxide layer 201 may be formed in a temperature range of 750 to 800 degrees Celsius using a wet or dry oxidization method. The pad nitride layer 202 may be formed to a thickness of 50 to 200 angstrom using a Low Pressure Vapor Deposition (LPCVD).

Referring to FIG. 2B, trenches 204 are formed by sequentially etching the hard mask layer 203, the pad nitride layer 202, the screen oxide layer 201 and the semiconductor substrate 200. A liner oxide layer 205 is formed in order to decrease etch damage caused by the trench etch process and mitigate stress of the semiconductor substrate 200 due to the shrinkage of a gap-fill material, which will gap fill the inside of the trenches 204 in a subsequent process.

The trench etch process may be performed so that the sidewall of the trenches 304 is inclined at a tilt angle of 75 to 87 degrees. This enables the gap-fill material to easily flow into the trenches 204 at the time of the gap-fill process. The liner oxide layer 205 may be formed to a thickness of 50 to 250 angstrom using any one of a CVD process, a PECVD process, a thermal oxidization process and a radical oxidization process.

Referring to FIG. 2C, a PSZ layer 206 is formed sufficiently enough to gap fill the trenches 204. In one embodiment, the PSZ layer 206 is formed to a thickness of 3,000 to 9,000 angstrom in devices having an isolation layer width of 70 nm or less. The PSZ layer 206 is annealed.

After the annealing process of the PSZ layer 206 is completed, the PSZ layer 206, the hard mask layer 203, the pad nitride layer 202 and the screen oxide layer 201 are removed using a polishing process, such as a CMP process. The PSZ layer 206 that remains within the trenches 204 forms isolation layers 206a as shown in FIG. 2D.

As described above, in certain embodiments of the present invention, the isolation layers 206a is formed from a PSZ material. Typically, the PSZ material contains a large quantity of impurities. Thus, if the isolation layers 206a are formed in the trenches 204 while impurities are not properly removed after the PSZ layer 206 is formed, not only voids are generated in the isolation layers 206a, but also the impurities remaining in the isolation layers 206a have an effect on a subsequent process, causing device failure. There have been many attempts to remove impurities after the PSZ layer 206 is formed. Conventionally, the annealing process employing an oxygen gas has been used remove impurities. Such annealing process, however, does not remove impurities to a satisfactory level and does not perform adequate SiO₂ combination.

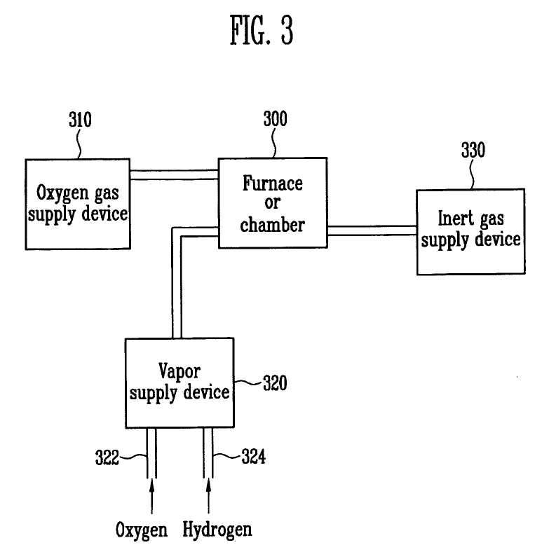

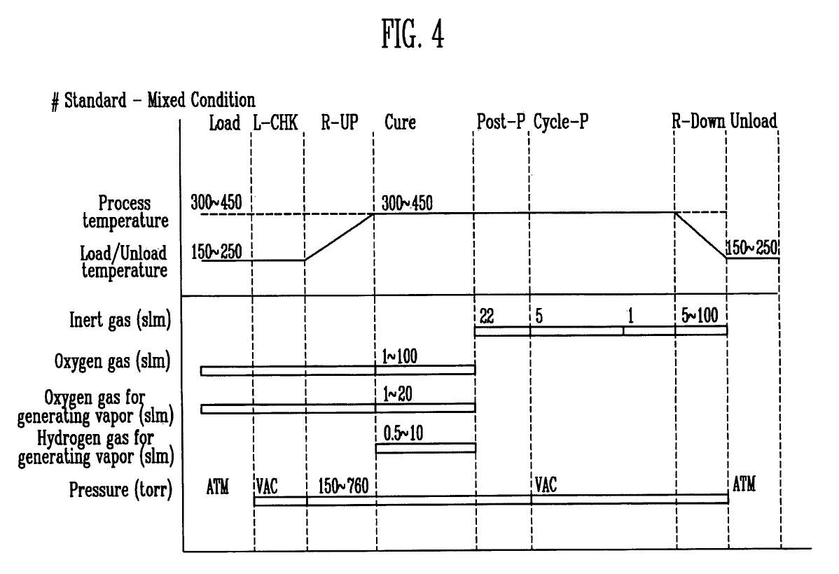

With reference to FIGS. 3 and 4, the annealing process of the PSZ layer 206 according to an embodiment of the present invention is described in detail below. The annealing process is performed in an annealing system of FIG. 3. The annealing system includes a furnace or chamber 300 in which a wafer having the PSZ layer 206 formed thereon is loaded and annealed, an oxygen gas supply device 310 for supplying an oxygen gas to the furnace or chamber 300, a vapor supply device 320 for supplying vapor to the furnace or chamber 300, and an inert gas supply device 330 for supplying an inert gas, such as N₂ gas, He gas or Ar gas, to the furnace or chamber 300. The vapor supply device 320 is equipped with an oxygen gas inlet port 322 and a hydrogen gas inlet port 324. The vapor supply device 320 includes all kinds of proper systems, such as a torch type, a water vapor generation type, and a water vaporizing type, which can be applied to a wet oxidization process of a semiconductor fabrication process. Hereinafter, the annealing process is described in detail step by step.

A first step is a step of loading a wafer having the PSZ layer 206 formed thereon into the chamber 300. A temperature within the chamber 300 is maintained to 150 to 250 degrees Celsius (that is, a loading temperature). An oxygen gas is supplied from the oxygen gas supply device 310 to the chamber 300 at the flow rate of 1 to 100 slm and is supplied from the oxygen gas inlet port 322, coupled to the vapor supply device 320, to the chamber 300 at the flow rate of 1 to 20 slm. A pressure within the chamber 300 is maintained to the atmospheric pressure.

Meanwhile, in the first step, the oxygen gas may be supplied from the oxygen gas supply device 310 to the chamber 300, but may not be supplied from the oxygen gas inlet port 322.

A second step is a step of checking the possibility of gas leakage of the chamber 300 since the results of the annealing step can be varied when the equipment is abnormal. In the gas leakage check step, the inside of the chamber 300 gradually becomes a vacuum state. The gas leakage check step may be performed in the atmospheric pressure state without making the inside of the chamber 300 the vacuum state. At this time, the temperature and the supply of the oxygen gas are maintained in the similar manner as described in the loading step.

A third step is a ramp-up step of raising the temperature within the chamber 300 up to 300 to 450 degrees Celsius (that is, a process temperature). The ramp-up step may be performed by maintaining the pressure within the chamber 300 at a vacuum pressure. The vacuum pressure, as used herein, refers to a pressure which is lower than the atmospheric pressure, but higher than 150 Torr. Alternatively, the ramp-up step may be performed by maintaining the pressure within the chamber 300 at the atmospheric pressure. At this time, the supply of the oxygen gas is maintained as in the gas leakage check step.

A fourth step is a step of curing the PSZ layer 206 in order to remove impurities contained in the PSZ layer 206. The curing step may be performed by maintaining the temperature within the chamber 300 to 300 to 450 degrees Celsius (that is, the process temperature) in a state where the oxygen gas and vapor are mixed. A pressure at this time is maintained in the similar manner as described in the ramp-up step.

If a hydrogen gas is injected into the vapor supply device 320 through the hydrogen gas inlet port 324 in a state where the oxygen gas is continuously supplied from the oxygen gas inlet port 322 to the vapor supply device 320, vapor is created through a reaction of the oxygen and the hydrogen in the vapor supply device 320. The created vapor is supplied to the chamber 300 at the flow rate of 1 to 30 slm. Consequently, the oxygen gas supplied from the oxygen gas supply device 310 at the flow rate of 1 to 100 slm and the vapor supplied from the vapor supply device 320 at the flow rate of 1 to 30 slm are mixed in the chamber 300. In this state, the PSZ layer 206 is cured.

In one embodiment, the process of the first step is carried out without having the oxygen gas supplied from the oxygen gas inlet port 322. In that embodiment, the oxygen and the hydrogen react to each other in the vapor supply device 320 in order to create vapor. The created vapor is supplied to the chamber 300 when the curing step begins. That is, the methods of supplying vapor may differ among embodiments, generally depending on the process of the first step.

In the curing step, a curing time is decided according to the thickness of the PSZ layer 206. In devices having an isolation layer width of 70 nm or less, when the PSZ layer 206 is formed to a thickness of 3,000 to 9,000 angstrom, the curing time may be set in the range of 10 to 600 minutes.

The curing step is preferably performed in a state where the ratio of the oxygen gas and the vapor is set in the range of approximately 1:1 to approximately 50:1. It is noted that when the oxygen gas and the vapor are mixed in a ratio smaller than 1:1, for example, 1:1.3, moats can be create on the sidewalls of the trenches due to the excessive vapor. When the oxygen gas and the vapor are mixed in a ratio greater than 50:1, for example, 66:1, not only impurities included in the PSZ layer 206 may not be removed to a satisfactory level due to an excessive oxygen gas, but also the PSZ layer 206 formed at a portion where the distance between patterns is wide may collapse. In other words, it is undesirable if the curing step is performed in a state where the amount of the oxygen gas is small compared to the vapor, for example, 50% or less, or if the curing step is performed in a state where the amount of the oxygen gas is great compared to the vapor, for example, 98% or more.

A fifth step is a post-processing step and is not illustrated in FIG. 4. The post-processing step may be selectively performed in order to further densify the film quality of the PSZ layer 206 on which the curing step has been performed. The post-processing step is performed using only the vapor in a state where the oxygen gas supplied from the oxygen gas supply device 310 is blocked. At this time, a temperature and pressure are maintained in the similar manner as described in the curing step.

A sixth step is a purge step which is performed by supplying an inert gas, such as N₂ gas, He gas or Ar gas, into the chamber 300 from the inert gas supply device 330 in a state where the oxygen gas and vapor supplied into the chamber 300 are all blocked. In this step, a temperature is maintained in the similar manner as described in the curing step and a pressure is maintained at the atmospheric pressure.

In one embodiment, the purge step can be divided into a post purge step and a cycle purge step, as shown in FIG. 4. The post purge step may be performed by supplying the inert gas from the inert gas supply device 330 to the chamber 300 in a state where the supply of the oxygen gas and vapor to the chamber 300 is blocked. At this time, the inert gas is supplied to the chamber 300 at the flow rate of about 22 slm. The cycle purge step may be performed while changing the flow rate of the inert gas after the post purge step. For example, the flow rate may be changed by first supplying the inert gas of 5 slm and then supplying the inert gas of 1 slm. In the post purge step and the cycle purge step, a temperature is maintained in the similar manner as described in the curing step. Note that a pressure is maintained at the atmospheric pressure during the cycle purge step.

A seventh step is a ramp-down step of lowering the temperature within the chamber 300 down to 150 to 250 degrees Celsius while supplying the inert gas from the inert gas supply device 330 to the chamber 300 at the flow rate of 5 to 100 slm in a state where the pressure within the chamber 300 is maintained to the atmospheric pressure.

An eighth step is a step of unloading the wafer having the PSZ layer 206 formed thereon outside the chamber 300. The annealing step of the PSZ layer 206 is thereby completed.

The above-mentioned annealing step may be divided into two embodiments and applied to the present invention. The annealing step according to one embodiment includes performing all the first to eighth steps, and the annealing step according to the second embodiment is performed except for the fifth step of the first to eighth steps. That is, the post-processing step of the fifth step is advantageous in that it can further densify the film quality of the PSZ layer 206, but is disadvantageous in that it increases an annealing step time. If impurities remaining in the PSZ isolation layers 206a do not serve as device failure even if the post-processing step is not performed, it is advantageous to apply the annealing step according to the second embodiment, but otherwise it is advantageous to apply the annealing step according to such embodiment.

As discussed above, the annealing step of some embodiments is performed using an oxygen gas and vapor. The oxygen gas functions to make uniform curing over the entire PSZ layer 206 rather than curing a portion of the PSZ layer 206. The vapor functions to remove impurities included in the PSZ layer 206 and increase the denseness of the film. There is no significant difference in the degree of curing in the depth direction in a region where the distance between patterns covered with the PSZ layer 206 is wide (for example, a peri region) since the diffusion and infiltration of vapor are free in such regions. However, there is a difference in the degree of curing in the depth direction in a region where the distance between patterns covered with the PSZ layer 206 is narrow (for example, a cell region). This is because the diffusion of vapor is not free and the infiltration of vapor is also difficult in such regions.

In some embodiments, the oxygen gas is supplied to the chamber 300 at a step before the curing step is performed so that a large amount of the oxygen gas can be infiltrated into the PSZ layer 206. Due to such step, the diffusion and infiltration of vapor supplied in the curing step may be more easily avoided, thus the curing effect can be maximized. It is noted that it is important to control the supply ratio of the oxygen gas and vapor supplied in the curing step as described above.

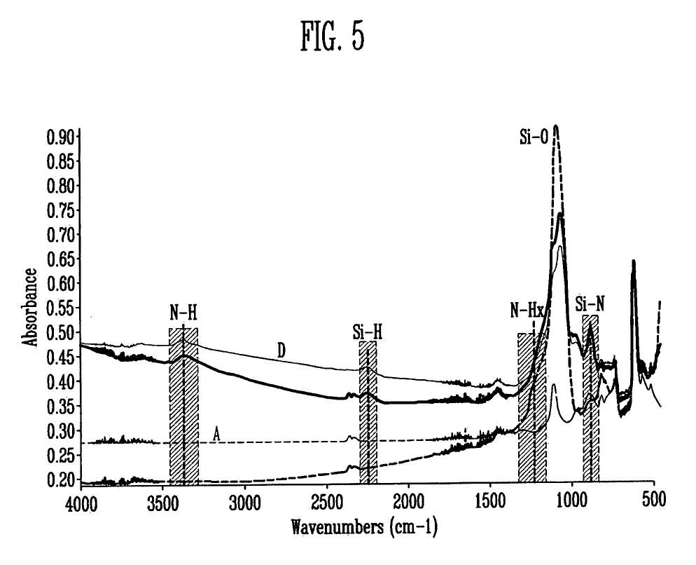

FIG. 5 illustrates combined energy analysis results obtained by employing the FTIR spectrometer according to an embodiment of the present invention.

It is noted that the PSZ layer 206 on which the annealing step of certain embodiments of the present invention has been performed may secure the film quality of a level similar to that of a SiO₂ layer and the reflection index (RI) is almost similar to that of a SiO₂ layer in an optical analysis employing a wavelength. However, the level of impurities caused by N, H, etc., which are first included in the PSZ layer 206, can be decided according to the ratio of the oxygen gas and vapor applied during the annealing step as discussed above. Accordingly, the ratio of an adequate level can be secured according to the amount of impurities of the PSZ layer 206, a coated thickness, the depth of a trench, the type of an underlying layer formed before coating and/or the like. A process margin, enabling easy control of the Effective Field Oxide Height (EFH), can be secured and impurities can be reduced in a subsequent process by employing these process procedures and conditions, and therefore the yield of devices can be improved.

The present invention is not limited to the disclosed embodiments, but may be implemented in various manners. The embodiments are provided to complete the disclosure of the present invention and to allow those having ordinary skill in the art to understand the scope of the present invention. The present invention is defined by the category of the claims.

As described above, according to some embodiments of the present invention, a PSZ material having an excellent gap-fill characteristic is used as material for forming the Isolation layer. Accordingly, high-integrated devices of 70 nm or less, which have excellent reliability and electrical property, can be implemented.

What is claimed is:

1. An annealing method of a polysilizane (PSZ) layer, comprising:
loading a wafer on which the PSZ layer is formed into a chamber in which a loading temperature is maintained, wherein an oxygen gas is supplied to the chamber;
curing the PSZ layer in a state where the process temperature is maintained in the chamber, wherein vapor is supplied to the chamber, and a ratio of the oxygen gas and the vapor is set in the range of approximately 1:1 to approximately 50:1;
purging the inside of the chamber by blocking both the oxygen gas and the vapor supplied to the chamber;
supplying an inert gas to the chamber; and
unloading the wafer outside the chamber in a state where an unloading temperature is maintained in the chamber.

2. The method of claim 1, further comprising, after loading the wafer, raising a temperature within the chamber from the loading temperature to the process temperature, wherein the loading temperature ranges from 150 to 250 degrees Celsius.

3. The method of claim 1, wherein the oxygen gas is supplied to the chamber through an oxygen gas inlet port which is coupled to a vapor supply device and through an oxygen gas supply device.

4. The method of claim 3, wherein the oxygen gas is supplied to the chamber at a flow rate of 1 to 100 slm from the oxygen gas supply device to the chamber and is supplied to at a flow rate of 1 to 20 slm from the oxygen gas inlet port to the chamber.

5. The method of claim 1, wherein the oxygen gas is supplied from an oxygen gas supply device to the chamber.

6. The method of claim 1, wherein the process temperature ranges from 300 to 450 degrees Celsius.

7. The method of claim 1, wherein the vapor is supplied to the chamber through a vapor supply device.

8. The method of claim 1, wherein the inert gas is supplied to the chamber through an inert gas supply device.

9. The method of claim 1, wherein the purging step is performed using a post purge step and a cycle purge step.

10. The method of claim 1, wherein a pressure in the loading step and the unloading step is maintained at an atmospheric pressure, and a pressure in the entire steps other than the loading step and the unloading step is maintained at a pressure which is lower than the atmospheric pressure, but higher than 150 Torr.

11. The method of claim 1, further comprising checking a gas leakage possibility of the chamber after the loading step.

12. The method of claim 1, further comprising post-processing using only the vapor, wherein the oxygen gas is blocked after the curing step.

13. The method of claim 1, further comprising, before unloading the wafer, lowering a temperature within the chamber from the process temperature to the unloading temperature, wherein the unloading temperature ranges from 150 to 250 degrees Celsius.

14. A method of forming an isolation layer of a semiconductor device, comprising:
forming a PSZ layer over a substrate in which trenches are formed;
loading a wafer on which the PSZ layer is formed into a chamber in which a loading temperature is maintained wherein an oxygen gas is supplied to the chamber;
after loading the wafer, raising a temperature within the chamber from the loading temperature to a process temperature;
curing the PSZ layer in a state where the process temperature is maintained, wherein vapor is supplied to the chamber, and a ratio of the oxygen gas and the vapor in the chamber is set in the range of approximately 1:1 to approximately 50:1;
purging the inside of the chamber by supplying an inert gas to the chamber, wherein both the oxygen gas and the vapor supplied to the chamber are blocked;
lowering the temperature within the chamber from the process temperature to an unloading temperature;
unloading the wafer outside the chamber in a state where the unloading temperature is maintained; and
forming the isolation layer within the trenches by polishing the PSZ layer using a Chemical Mechanical Polishing (CMP) process.

15. The method of claim 14, wherein the loading temperature and the unloading temperature range from 150 to 250 degrees Celsius.

16. The method of claim 14, wherein the oxygen gas is supplied to the chamber through an oxygen gas inlet port which is coupled to a vapor supply device and through an oxygen gas supply device.

17. The method of claim 16, wherein the oxygen gas is supplied to the chamber at a flow rate of 1 to 100 slm from the oxygen gas supply device and is supplied to the chamber at a flow rate of 1 to 20 slm from the oxygen gas inlet port which is coupled to the vapor supply device.

18. The method of claim 14, wherein the oxygen gas is supplied from an oxygen gas supply device to the chamber.

19. The method of claim 14, wherein the process temperature ranges from 300 to 450 degrees Celsius.

20. The method of claim 14, wherein the vapor is supplied to the chamber through a vapor supply device.

21. The method of claim 14, wherein the inert gas is supplied to the chamber through an inert gas supply device.

22. The method of claim 14, wherein the purging step is performed using a post purge step and a cycle purge step.

23. The method of claim 14, wherein a pressure in the loading step and the unloading step is maintained at an atmospheric pressure, and a pressure in the steps other than the loading step and the unloading step is maintained at a vacuum pressure which is lower than the atmospheric pressure, but higher than 150 Torr.

24. The method of claim 14, further comprising checking a gas leakage possibility of the chamber after the loading step.

25. The method of claim 14, further comprising post-processing using only the vapor in a state where the oxygen gas is blocked after the curing step.
